(19) United States
(12) Patent Application Publication
(10) Pub. No.: US 2026/0096021 A1
(43) Pub. Date: Apr. 2, 2026

(54) WIRING CIRCUIT BOARD

(71) Applicant: NITTO DENKO CORPORATION, Osaka (JP)

(72) Inventors: Hiroki YAMAGUCHI, Osaka (JP); Hayato TAKAKURA, Osaka (JP); Keigo KOGUCHI, Osaka (JP)

(73) Assignee: NITTO DENKO CORPORATION, Osaka (JP)

(21) Appl. No.: 19/340,326

(22) Filed: Sep. 25, 2025

(30) Foreign Application Priority Data
Sep. 30, 2024 (JP) 2024-171085

(51) Int. Cl. H05K 1/02; H05K 1/05

(52) U.S. Cl. CPC H05K 1/0296; H05K 1/05; H05K 2201/09027

(57) ABSTRACT

A wiring circuit board includes a wiring portion and a first support portion that supports one end portion of the wiring portion. The wiring portion includes a metal support layer, a first insulating layer, and a wire. The wire includes a first conductor layer disposed on the first insulating layer, and a second conductor layer covering the first conductor layer and in contact with the first insulating layer. The ratio (T11/T21) of the thickness T11 of the wire to the thickness T21 of the first conductor layer is 2.0 or more.

### CROSS-REFERENCE TO RELATED APPLICATION

The present application claims priority from Japanese Patent Application No. 2024-171085 filed on Sep. 30, 2024, the content of which is hereby incorporated by reference into this application.

### TECHNICAL FIELD

The present invention relates to a wiring circuit board.

### BACKGROUND ART

Conventionally, there has been a known wiring circuit board including a plurality of wiring bodies spaced away from each other in parallel has been known (for example, see Patent Document 1 below). The wiring body includes a wire (main wiring portion).

### CITATION LIST

### Patent Document

Patent Document 1: Japanese Unexamined Patent Publication No. 2019-212656

### SUMMARY OF THE INVENTION

### Problem to be Solved by the Invention

For the wiring circuit board as described in Patent Document 1, reducing the electrical resistance of the wire may be desirable, for example, when the increase in the current flowing through the wire (main wiring portion) is required.

The present invention provides a wiring circuit board capable of reducing the electrical resistance of the wire.

### Means for Solving the Problem

The present invention [1] includes a wiring circuit board comprising: a wiring portion; and a support portion that supports one end portion of the wiring portion, wherein the wiring portion includes a metal support layer, an insulating layer disposed on the metal support layer, and a wire disposed on the insulating layer, wherein at least in the wiring portion, the wire includes: a first conductor layer disposed on the insulating layer, and a second conductor layer covering the first conductor layer and being in contact with the insulating layer, and wherein a ratio of a thickness of the wire to a thickness of the first conductor layer is 2.0 or more.

The present invention [2] includes the wiring circuit board described in the above-described [1], wherein a ratio of the thickness of the first conductor layer to a width of the first conductor layer is 0.3 or more and 1.1 or less.

The present invention [3] includes the wiring circuit board described in the above-described [1] or [2], wherein a width of the wire is larger than the width of the first conductor layer.

The present invention [4] includes the wiring circuit board described in any one of the above-described [1] to [3], wherein a distance between each of both side surfaces of the wire and the first conductor layer in a width direction of the wire is 10.00 μm or more.

The present invention [5] includes the wiring circuit board described in any one of the above-described [1] to [4], wherein the wire has a central portion and an end portion in a width direction of the wire, and wherein the central portion protrudes toward an opposite side to the metal support layer with respect to the insulating layer in the thickness direction as compared with the end portion.

The present invention [6] includes the wiring circuit board described in any one of the above-described [1] to [5], wherein the wire has a concave portion on each of both side surfaces of the wire in a width direction of the wire, and wherein a depth of the concave portion is 0.7 μm or less.

The present invention [7] includes the wiring circuit board described in any one of the above-described [1] to [6], wherein the support portion includes a wire that is continuous with the wire of the wiring portion, and wherein the wire of the support portion includes the first conductor layer and the second conductor layer.

The present invention [8] includes the wiring circuit board described in any one of the above-described [1] to [7], wherein the wiring circuit board includes a plurality of the wiring portions spaced away from each other, and wherein the support portion supports one end portion of each of the plurality of the wiring portions.

### Effects of the Invention

According to the wiring circuit board of the present invention, at least in the wiring portion, the wire includes a first conductor layer and a second conductor layer.

The second conductor layer covers the first conductor layer and is in contact with the insulating layer. Therefore, both the width of the wire and the thickness of the wire can be increased by the second conductor layer as compared with the case where the wire is formed only from the first conductor layer.

As a result, the cross-sectional area of the wire can be increased, and the electrical resistance of the wire can be reduced.

Here, the second conductor layer can be formed by the plating growth in both the width direction and the thickness direction using the first conductor layer as a seed. In this case, the plating growth in the width direction is inhibited by the plating resist, and a concave portion (a portion where the plating growth is inhibited) may be formed on a side surface of the wire.

If an excessively deep concave portion is formed on a side surface of the wire, the concave portion may cause the increase in the electrical resistance of the wire, and the electrical resistance of the wire may not be sufficiently reduced.

In this regard, the ratio of the thickness of the wire to the thickness of the first conductor layer is 2.0 or more.

Therefore, the depth of the concave portion can be reduced, and the electrical resistance of the wire can be reduced more reliably.

### BRIEF DESCRIPTION OF THE DRAWINGS

FIG. 1 is a plan view of a wiring circuit board as one embodiment of the present invention. In FIG. 1, the second insulating layer is omitted.

FIG. 2A is a cross-sectional view of the wiring circuit board shown in FIG. 1, taken along line A-A. FIG. 2B is a cross-sectional view of the wiring circuit board shown in FIG. 1, taken along line B-B.

FIGS. 3A and 3B are process diagrams for explaining a method of producing the wiring circuit board. FIG. 3A shows a first insulating layer forming step. FIG. 3B shows a first conductor layer forming step.

FIGS. 4A and 4B are process diagrams for explaining the method of producing the wiring circuit board, following FIG. 3B. FIG. 4A shows a second conductor layer forming step.

FIG. 4B shows a second insulating layer forming step.

FIG. 5 shows a wiring circuit board of a modified example.

### DESCRIPTION OF THE EMBODIMENT

### 1. Wiring Circuit Board

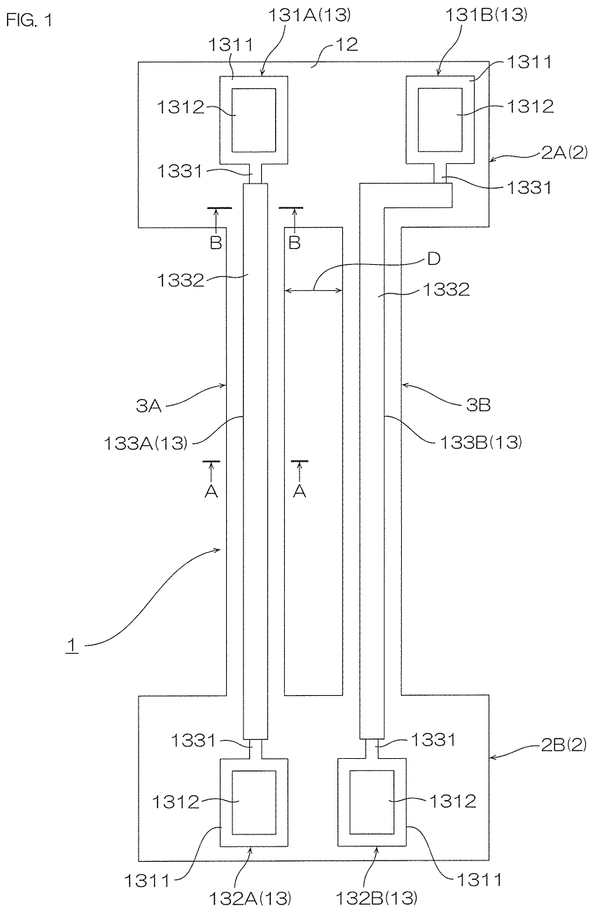

As shown in FIG. 1, a wiring circuit board 1 includes a plurality of support portions 2 (in the present embodiment, a first support portion 2A and a second support portion 2B) and a plurality of wiring portions 3A and 3B.

The first support portion 2A and the second support portion 2B are spaced apart from each other. The shapes of the first support portion 2A and the second support portion 2B are not limited. The first support portion 2A supports one end portion of each of the wiring portions 3A and 3B. Terminals 131A and 131B of a conductive pattern 13 described later may be disposed in the first support portion 2A. The second support portion 2B supports the other end portion of each of the wiring portions 3A and 3B. Terminals 132A and 132B of the conductive pattern 13 described later may be disposed in the second support portion 2B.

The wiring portions 3A and 3B are disposed between the first support portion 2A and the second support portion 2B. At least a part of a wire 133A described later is disposed in the wiring portion 3A. The wiring portion 3A has a width in a width direction of the wire 133A (the wire 133A of the wiring portion 3A), and extends in a direction in which the wire 133A (the wire 133A of the wiring portion 3A) extends. The width direction is orthogonal to the thickness direction of the wiring circuit board 1. The direction in which the wire 133A extends is perpendicular to the width direction and the thickness direction. At least a part of a wire 133B described later is disposed in the wiring portion 3B. The wiring portion 3B has a width in a width direction of the wiring 133B (the wiring 133B of the wiring portion 3B), and extends in a direction in which the wiring 133B (the wiring 133B of the wiring portion 3B) extends. In the present embodiment, the wiring portion 3B extends in the same direction as the wiring portion 3A. One end portion of each of the wiring portions 3A and 3B is connected to the first support portion 2A. The other end portion of each of the wiring portions 3A and 3B is connected to the second support portion 2B. The shape of each of the wiring portions 3A and 3B are not limited. Each of the wiring portions 3A and 3B may have a linear shape or be curved. In the present embodiment, the wires 133A and 133B are arranged in the width direction of the wire 133A. The wiring portions 3A and 3B are spaced apart from each other by an interval D in the width direction of the wire 133A.

The interval D between the wiring portion 3A and the wiring portion 3B is, for example, 5 μm to 300 μm, preferably 10 μm to 250 μm.

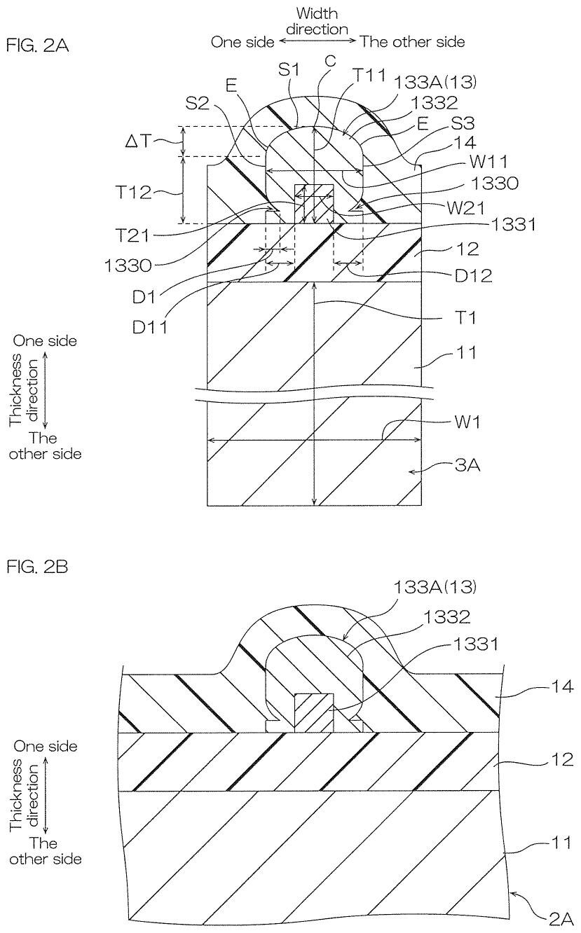

As shown in FIGS. 2A and 2B, the wiring circuit board 1 includes a metal support layer 11, a first insulating layer 12 as an example of an insulating layer, a conductive pattern 13, and a second insulating layer 14.

### (1) Metal Support Layer

The metal support layer 11 is disposed in the support portion 2 (the first support portion 2A and the second support portion 2B) and the wiring portions 3A and 3B. That is, the wiring portions 3A and 3B include the metal support layer 11. The metal support layer 11 supports the first insulating layer 12, the conductive pattern 13, and the second insulating layer 14. The metal support layer 11 is made of metal. Examples of the material of the metal support layer 11 include, for example, copper, nickel, cobalt, iron, and the alloys thereof. Examples of the alloy include stainless steel and a copper alloy. As the material of the metal support layer 11, preferably a copper alloy is used.

The metal support layer 11 has a thickness T1 of, for example, 10 μm to 300 μm, preferably 50 μm to 250 μm.

As shown in FIG. 2A, in the wiring portion 3A, the metal support layer 11 has a width W1 of, for example, 5 μm to 300 μm, preferably 10 μm to 250 μm.

In the wiring portion 3A, the ratio (T1/W1) of a thickness T1 of the metal support layer 11 to the width W1 of the metal support layer 11 is 2 or more, preferably 5 or more. When the ratio (T1/W1) is the above-described lower limit or more, the stiffness of the wiring portion 3A in the thickness direction can be ensured. The ratio (T1/W1) is, for example, 30 or less, preferably 10 or less. The ratio (T1/W1) may be 2 to 30, or 5 to 10.

### (2) First Insulating Layer

The first insulating layer 12 is disposed in the support portion 2 (the first support portion 2A and the second support portion 2B) and the wiring portions 3A and 3B. That is, the wiring portions 3A and 3B include the first insulating layer 12. The first insulating layer 12 is disposed at one side of the metal support layer 11 in the thickness direction of the metal support layer 11. The first insulating layer 12 is disposed on the metal support layer 11.

The first insulating layer 12 may be disposed on the metal support layer 11 via a protective metal layer (first protective metal layer). In other words, the wiring circuit board 1 may include a protective metal layer disposed between the metal support layer 11 and the first insulating layer 12 in the thickness direction. The protective metal layer protects the metal support layer 11. The protective metal layer is, for example, a sputtering layer disposed on a one-side surface of the metal support layer 11 in the thickness direction. Examples of the material for the protective metal layer include, for example, chromium, copper, nickel, titanium, and the alloys thereof.

The first insulating layer 12 is disposed between the metal support layer 11 and the conductive pattern 13 in the thickness direction. The first insulating layer 12 insulates the metal support layer 11 from the conductive pattern 13. The first insulating layer 12 is made of resin. Examples of the resin include polyimide, maleimide, epoxy resin, polybenzoxazole, and polyester.

### (3) Conductive Pattern

The conductive pattern 13 is disposed at one side of the first insulating layer 12 in the thickness direction. The conductive pattern 13 is disposed on the first insulating layer 12. That is, the wires 133A and 133B are disposed on the first insulating layer 12.

Note that the conductive pattern 13 may be disposed on the first insulating layer 12 via a protective metal layer (second protective metal layer). In other words, the wiring circuit board 1 may include a protective metal layer disposed between the first insulating layer 12 and the conductive pattern 13 in the thickness direction. The protective metal layer protects the conductive pattern 13. The protective metal layer is, for example, a sputtering layer disposed on a one-side surface of the first insulating layer 12 in the thickness direction. Examples of the material for the protective metal layer include chromium, copper, nickel, titanium, and the alloys thereof.

The conductive pattern 13 is disposed on an opposite side to the metal support layer 11 with respect to the first insulating layer 12 in the thickness direction. The shape of the conductive pattern 13 is not limited.

As shown in FIG. 1, the conductive pattern 13 includes, for example, a plurality of terminals 131A and 131B, a plurality of terminals 132A and 132B, and a plurality of wires 133A and 133B.

The terminals 131A and 131B are disposed in the first support portion 2A. Each of the terminals 131A and 131B has a square land shape. The terminal 131B is disposed away from the terminal 131A.

The terminals 132A and 132B are disposed in the second support portion 2B. Each of the terminals 132A and 132B has a square land shape. The terminal 132B is disposed away from the terminal 132A.

Each of the terminals 131A, 131B, 132A, and 132B includes a first conductor layer 1311 and a second conductor layer 1312.

The first conductor layer 1311 is disposed between the first insulating layer 12 and the second conductor layer 1312 in the thickness direction. The first conductor layer 1311 is disposed on the first insulating layer 12. The first conductor layer 1311 is made of metal. Examples of the metal include copper, silver, gold, iron, aluminum, chromium, and the alloys thereof. To obtain good electrical properties, as the metal, preferably copper is used.

The second conductor layer 1312 is disposed at one side of the first conductor layer 1311 in the thickness direction. The second conductor layer 1312 is disposed on the first conductor layer 1311. The second conductor layer 1312 is not in contact with the first insulating layer 12. The second conductor layer 1312 is made of metal. As the metal, the same metal as that of the first conductor layer 1311 is used. The second conductor layer 1312 is preferably made of the same metal as that of the first conductor layer 1311.

The wire 133A electrically connects the terminal 131A and the terminal 132A. One end portion of the wire 133A is connected to the terminal 131A. The other end portion of the wire 133A is connected to the terminal 132A. At least a part of the wire 133A is disposed in the wiring portion 3A. That is, the wiring portion 3A includes the wire 133A. One end portion of the wire 133A may be disposed in the first support portion 2A. The other end portion of the wire 133A may be disposed in the second support portion 2B. That is, the support portion 2 may include a part of the wire 133A. The wire 133A of the support portion 2 is continuous with the wire 133A of the wiring portion 3A.

The wire 133B electrically connects the terminal 131B and the terminal 132B. One end portion of the wire 133B is connected to the terminal 131B. The other end portion of the wire 133B is connected to the terminal 132B. At least a part of the wire 133B is disposed in the wiring portion 3B. That is, the wiring portion 3B includes a wire 133B. One end portion of the wire 133B may be disposed in the first support portion 2A. The other end portion of the wire 133B may be disposed in the second support portion 2B. That is, the support portion 2 may include a part of the wire 133B. The wiring 133B of the support portion 2 is continuous with the wiring 133B of the wiring portion 3A.

The direction in which the wires 133A and 133B of the support portion 2 extend is not limited. The wires 133A and 133B of the support portion 2 may extend in a direction crossing a direction in which the wire 133A of the wiring portion 3A extends.

### (1-4) Second Insulating Layer

As shown in FIGS. 2A and 2B, the second insulating layer 14 is disposed at one side of the first insulating layer 12 in the thickness direction. The second insulating layer 14 is disposed on the first insulating layer 12. The second insulating layer 14 covers all the wires 133A and 133B. The second insulating layer 14 does not cover the terminals 131A, 131B, 132A, and 132B. The second insulating layer 14 is made of resin. Examples of the resin include polyimide, maleimide, epoxy resin, polybenzoxazole, and polyester.

### 2. Details of Wires

Next, with reference to FIG. 2A, the details of the wire 133A are described. The wire 133B has the same structure as that of the wire 133A. The description of the wire 133B is omitted.

The wire 133A has a central portion C and an end portion E in the width direction of the wire 133A. The central portion C is disposed at the center of the wire 133B in the width direction. The central portion C protrudes toward one side in the thickness direction as compared with the end portion E. In other words, the central portion C protrudes toward the opposite side to the metal support layer 11 with respect to the first insulating layer 12 in the thickness direction as compared with the end portion E. One end surface S1 of the wire 133A in the thickness direction has a substantially arc shape. Both side surfaces S2 and S3 of the wire 133A in the width direction extend in the thickness direction.

The wire 133A has a width W11 of, for example, 30 μm or more, preferably 35 μm or more. The width W11 of the wire 133A is, for example, 50 μm or less, preferably 45 μm or less.

The central portion C of the wire 133A has a thickness T11 of, for example, 30 μm or more, preferably 35 μm or more. The thickness T11 of the central portion C of the wire 133A is, for example, 50 μm or less, preferably 45 μm or less.

The ratio (T11/W11) of the thickness T11 of the central portion C to the width W11 of the wire 133A is, for example, 3.0 or less, preferably 2.0 or less, more preferably 1.7 or less, and more preferably 1.3 or less. When the ratio (T11/W11) is the above-described upper limit or less, an excessive increase in the stiffness of the wire 133A in the thickness direction can be suppressed. The ratio (T11/W11) is, for example, 0.1 or more, preferably 0.3 or more, more preferably 0.5 or more, and more preferably 0.8 or more. When the ratio (T11/W11) is the above-described lower limit or more, the stiffness of the wire 133A in the thickness direction can be increased with respect to the stiffness of the wire 133A in the width direction. The ratio (T11/W11) may be 0.1 to 3.0, 0.3 to 2.0, 0.5 to 1.7, or 0.8 to 1.3.

The difference ΔT between the thickness T11 of the central portion C and a thickness T12 of the end portion E is, for example, 10% or more, preferably 20% or more, and more preferably 25% or more of the thickness T11 of the central portion C. The percentage of the “difference ΔT between the thickness T11 of the central portion C and the thickness T12 of the end portion E” with respect to the thickness T11 of the central portion C is defined as the protrusion rate of the central portion C. When the protrusion rate of the central portion C is the above-mentioned lower limit or more, the stiffness of the wire in the thickness direction can reliably be increased. The protrusion rate of the central portion C is, for example, 70% or less, preferably 60% or less, more preferably 55% or less. When the protrusion rate of the central portion C is the above-described upper limit or less, the cross-sectional area of the wire can be ensured. Thus, the electrical resistance of the wire 133A can be reduced. The protrusion rate of the central portion C may be 10% to 70%, 20% to 60%, or 25% to 55%.

Furthermore, the wire 133A has a concave portion 1330 on both the side surfaces S2 and S3. The concave portion 1330 on the side surface S2 at one side in the width direction is concave toward the other side in the width direction. The concave portion 1330 on the side surface S3 at the other side in the width direction is concave toward the one side in the width direction. The concave portion 1330 on the side surface S2 and the concave portion 1330 on the side surface S3 are concave toward a first conductor layer 1331 described later in the width direction.

The concave portion 1330 has a depth D1 of, for example, 0.7 μm or less, preferably 0.5 μm or less. When the depth D1 of the concave portion 1330 is the above-described upper limit or less, an excessive reduction in the cross-sectional area of the wire can be suppressed. Thus, the electrical resistance of the wire 133A can be reduced. The depth D1 of the concave portion 1330 is, for example, 0.01 μm or more, preferably 0.05 μm or more. When the depth D1 of the concave portion 1330 is the above-described lower limit or more, the second insulating layer 14 enters the concave portion 1330. Thus, release of the second insulating layer 14 can be suppressed.

The wire 133A of the wiring portion 3A includes the first conductor layer 1331 and a second conductor layer 1332. As shown in FIG. 2B, the wire 133A of the support portion 2 may also include a first conductor layer 1331 and a second conductor layer 1332. In the present embodiment, the wire 133A consists of the first conductor layer 1331 and the second conductor layer 1332.

### (1) First Conductor Layer

As shown in FIG. 2A, the first conductor layer 1331 is disposed at one side of the first insulating layer 12 in the thickness direction. The first conductor layer 1331 is disposed on the first insulating layer 12. The first conductor layer 1331 is disposed in the central portion C of the wire 133A in the width direction. The first conductor layer 1331 is disposed between the concave portion 1330 on the side surface S2 and the concave portion 1330 on the side surface S3 in the width direction. The first conductor layer 1331 has a rectangular shape in the cross-sectional view. The first conductor layer 1331 is connected to the terminal 131A (see FIG. 1) and the terminal 132A (see FIG. 1). The first conductor layer 1331 is made of the same metal as that of the first conductor layer 1311 of the terminal 131A.

The first conductor layer 1331 has a width W21 of, for example, 1 μm or more, preferably 5 μm or more. The width W21 of the first conductor layer 1331 is, for example, 20 μm or less, preferably 15 μm or less.

The first conductor layer 1331 has a thickness T21 of, for example, 1 μm or more, preferably 5 μm or more. The thickness T21 of the first conductor layer 1331 is, for example, 20 μm or less, preferably 15 μm or less.

The ratio (T21/W21) of the thickness T21 of the first conductor layer 1331 to the width W21 of the first conductor layer 1331 is, for example, 0.3 or more, preferably 0.4 or more.

When the ratio (T21/W21) is the above-described lower limit or more, the protrusion rate of the central portion C of the second conductor layer 1332 can be increased. Thus, the stiffness of the wire in the thickness direction can be increased. The ratio (T21/W21) is, for example, 1.1 or less, preferably 0.5 or less. When the ratio (T21/W21) is the above-described upper limit or less, the depth of the concave portion 1330 on each of the side surfaces S2 and S3 can be reduced.

### (2) Second Conductor Layer

The second conductor layer 1332 is disposed at one side of the first insulating layer 12 in the thickness direction. The second conductor layer 1332 covers the first conductor layer 1331. Specifically, the second conductor layer 1332 covers all of the one-side surface of the first conductor layer 1331 in the thickness direction and both side surfaces of the first conductor layer 1331 in the width direction. The second conductor layer 1332 is disposed on the first insulating layer 12. The second conductor layer 1332 is in contact with the first insulating layer 12. The second conductor layer 1332 is made of the same metal as that of the second conductor layer 1312 (see FIG. 1) of the terminal 131A.

In the wiring portion 3A, the ratio (T11/T21) of the thickness T11 of the wire 133A to the thickness T21 of the first conductor layer 1331 is 2.0 or more, preferably 2.3 or more. When the ratio (T11/T21) is the above-described lower limit or more, the depth of the concave portion 1330 in each of the side surfaces S2 and S3 can be reduced. The upper limit of the ratio (T11/T21) is not limited. The ratio (T11/T21) may be 6.0 or less, 5.0 or less, or 4.0 or less.

The width W11 of the wire 133A is larger than the width W21 of the first conductor layer 1331. The ratio (W11/W21) of the width W11 of the wire 133A to the width W21 of the first conductor layer 1331 is, for example, 1.2 or more, preferably 2.0 or more. When the ratio (W11/W21) is the above-described lower limit or more, the cross-sectional area of the wire can be ensured. Thus, the electrical resistance of the wire 133A can be reduced. The upper limit of the ratio (T11/T21) is not limited. The ratio (W11/W21) is, for example, 3.0 or less.

In the width direction, each of a distances D11 between the side surface S2 of the wire 133A and the first conductor layer 1331 and a distance D12 between the side surface S3 of the wire 133A and the first conductor layer 1331 is, for example, 10.00 μm or more, preferably 10.50 μm or more. When each of the distances D11 and D12 is the above-described lower limit or more, the depth of the concave portion 1330 on each of the side surfaces S2 and S3 can be reduced. Each of the distances D11 and D12 is, for example, 15.00 μm or less, preferably 13.00 μm or less. When each of the distances D11 and D12 is the above-described upper limit or less, the thickness T11 of the wire 133A can be ensured.

### 3. Method of Producing Wiring Circuit Board

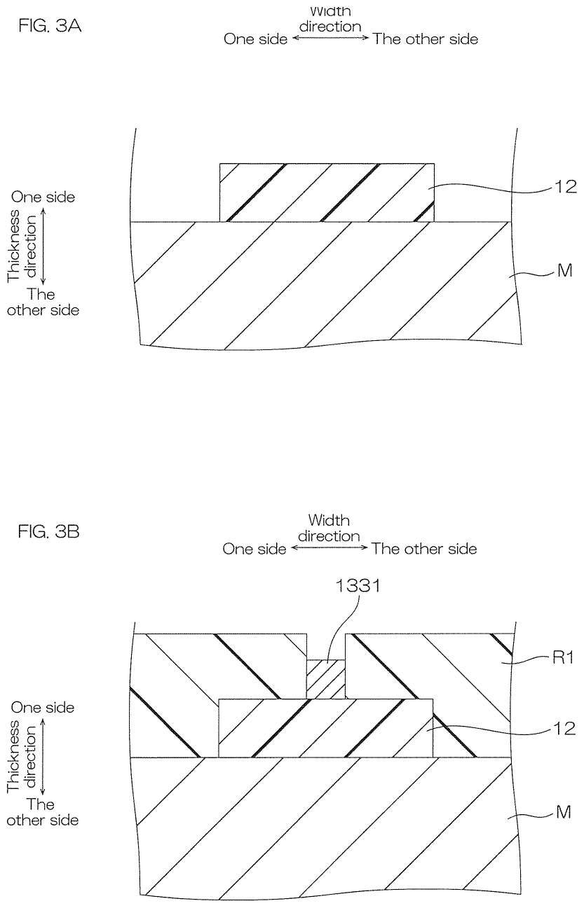

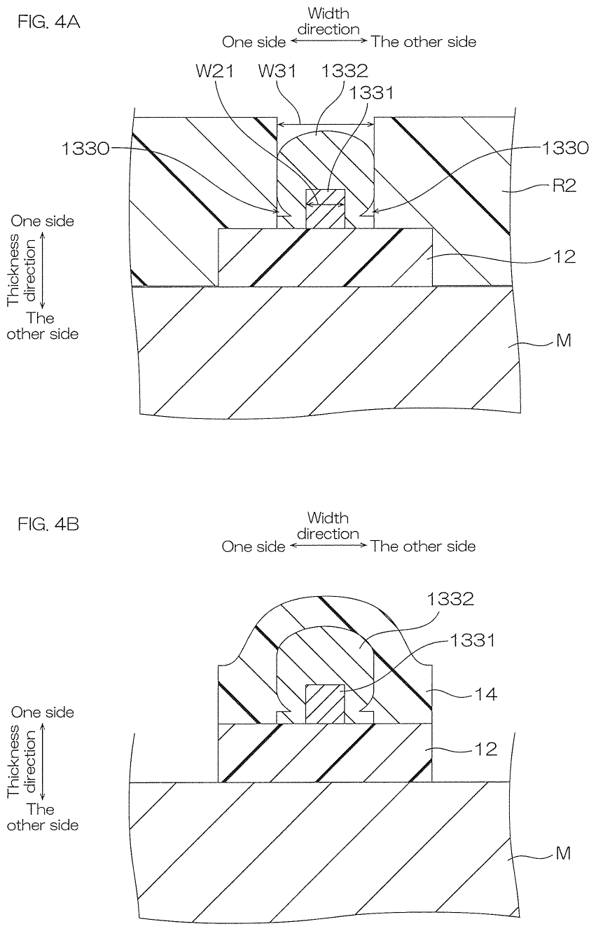

Next, with reference to FIGS. 3A to 4B, a method of producing the wiring circuit board 1 is described.

A method of producing the wiring circuit board 1 includes a first insulating layer forming step (see FIG. 3A), a first conductor layer forming step (see FIG. 3B), a second conductor layer forming step (see FIG. 4A), a second insulating layer forming step (see FIG. 4B), and an etching step.

### (1) First Insulating Layer Forming Step

As shown in FIG. 3A, in the first insulating layer forming step, a first insulating layer 12 is formed on a substrate M made of metal. Specifically, a solution (varnish) of a photosensitive resin is applied onto the substrate M and dried. By the drying, a coating film of the photosensitive resin is formed on the substrate M. Next, the coating film of the photosensitive resin is exposed to light and developed. By the development, the first insulating layer 12 is formed into a predetermined pattern on the substrate M.

### (2) First Conductor Layer Forming Step

Next, as shown in FIG. 3B, in the first conductor layer forming step, first conductor layers 1311 (see FIGS. 1) and 1331 are formed on the first insulating layer 12.

Specifically, first, a seed layer is formed on the surfaces of the first insulating layer 12 and the substrate M. The seed layer is formed, for example, by sputtering. Examples of the material of the seed layer include, for example, chromium, copper, nickel, titanium, and the alloys thereof.

Next, a plating resist R1 is attached to the substrate M. The plating resist R1 covers the first insulating layer 12.

Next, while the portion where the first conductor layers 1311 and 1331 are to be formed is shielded from light, the plating resist R1 is exposed to light and the plating resist R1 exposed to light is developed.

Then, the plating resist R1 in the shielded portion is removed, and the seed layer is exposed in the portion where the first conductor layers 1311 and 1331 are to be formed. On the other hand, the plating resist R1 in the portion exposed to light remains.

Next, the first conductor layers 1311 and 1331 are formed on the exposed seed layer by electrolytic plating.

After the electrolytic plating is completed, the plating resist R1 is released.

### (3) Second Conductor Layer Forming Step

Next, as shown in FIG. 4A, in the second conductor layer forming step, second conductor layers 1312 (see FIGS. 1) and 1332 are formed on the first insulating layer 12.

Specifically, first, a plating resist R2 is attached to the substrate M. The plating resist R2 covers the first insulating layer 12 and the first conductor layers 1311 and 1331.

Next, while the portion where the second conductor layers 1312 and 1332 are to be formed is shielded from light, the plating resist R2 is exposed to light, and the plating resist R2 exposed to light is developed.

Then, the plating resist R2 in the shielded portion is removed, and the seed layer and the first conductor layers 1311 and 1331 are exposed in the portion where the second conductor layers 1312 and 1332 are to be formed. On the other hand, the plating resist R2 in the portion exposed to light remains.

In the developed plating resist R2, the width W31 of the portion where the second conductor layer 1332 is to be formed is larger than the width W21 of the first conductor layer 1331. Furthermore, the first conductor layer 1331 is disposed in a central portion of the portion where the second conductor layer 1332 is to be formed in the width direction.

Next, the second conductor layer 1332 is formed on the exposed seed layer and the first conductor layer 1331 by electrolytic plating, and the second conductor layer 1312 is formed on the first conductor layer 1311.

By forming the second conductor layers 1312 and 1332, the above-described wires 133A and 133B and terminals 131A, 132A, 131B, and 132B are completed. In the central portion C of each of the wires 133A and 133B in the width direction, the second conductor layer 1332 is laminated on the first conductor layer 1331. On the other hand, in both end portions E of each of the wires 133A and 133B in the width direction, the second conductor layer 1332 is formed on the first insulating layer 12. Because the first conductor layer 1331 is disposed in the central portion C, the central portion C protrudes toward one side in the thickness direction as compared with the end portion E.

After the electrolytic plating is completed, the plating resist R2 is released. Thereafter, the seed layer exposed by the release of the plating resist R2 is removed by etching.

### (4) Second Insulating Layer Forming Step

Next, as shown in FIG. 4B, in the second insulating layer forming step, a second insulating layer 14 is formed on the first insulating layer 12 in the same manner as the formation of the first insulating layer 12.

### (5) Etching Step

Next, in the etching step, the substrate M is etched to form a metal support layer 11 (see FIG. 2A).

In this manner, the wiring circuit board 1 shown in FIG. 1 is produced.

### 4. Operations and Effects

According to the wiring circuit board 1, as shown in FIGS. 1 and 2A, at least in the wiring portion 3A, the wire 133A includes the first conductor layer 1331 and the second conductor layer 1332.

The second conductor layer 1332 covers the first conductor layer 1331 and is in contact with the first insulating layer 12. Therefore, as compared with the case where the wire 133A is formed only from the first conductor layer 1331, both the width W11 of the wire 133A and the thickness T11 of the wire 133A can be increased by the second conductor layer 1332.

Consequently, the cross-sectional area of the wire 133A can be increased, and the electrical resistance of the wire 133A can be reduced.

Here, as shown in FIG. 4A, the second conductor layer 1332 can be formed by the plating growth in both the width direction and the thickness direction using the first conductor layer 1331 as a seed. In this case, the plating growth in the width direction is inhibited by the plating resist R2, and a concave portion 1330 (a portion where the plating growth is inhibited) may be formed on the side surfaces S2 and S3 of the wire 133A.

When an excessively deep concave portion 1330 is formed on the side surfaces S2 and S3 of the wire 133A, the electric resistance of the wire 133A is increased due to the concave portions 1330. Thus, there is a possibility that the electric resistance of the wire 133A cannot be sufficiently reduced.

In this regard, the ratio (T11/T21) of the thickness T11 of the wire 133A to the thickness T21 of the first conductor layer 1331 is 2.0 or more.

Therefore, the depth D1 of the concave portion 1330 (see FIG. 2A) can be reduced, and the electrical resistance of the wire 133A can be reduced more reliably.

### 5. Modified Example

A Modified example is described. In the modified example, the same members as in the above-described embodiment are given the same numerical references and the descriptions thereof are omitted.

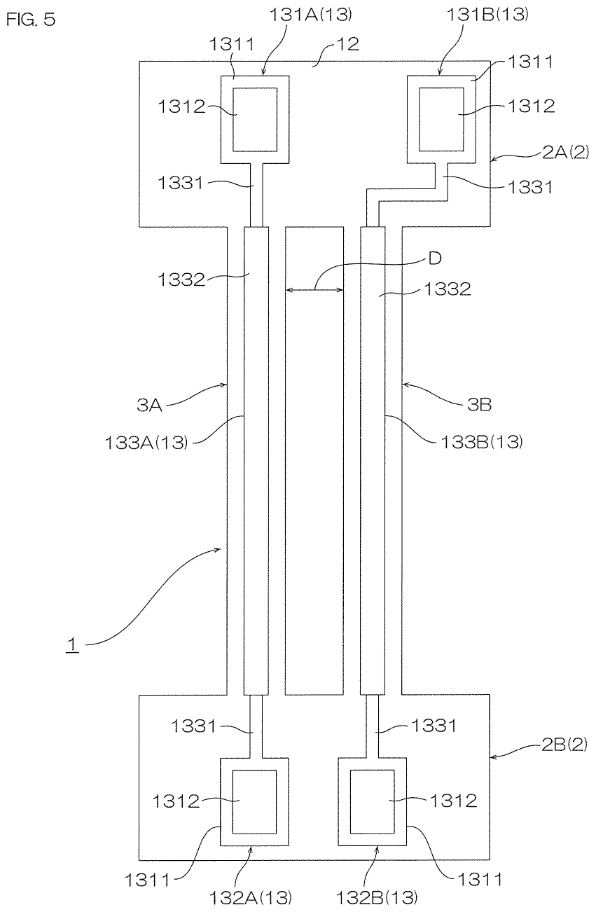

As shown in FIG. 5, the wires 133A and 133B of the support portion 2 may be formed only from the first conductor layers 1331.

Also in the modified example, the same operations and effects as in the above-described embodiment can be obtained.

### EXAMPLES

Hereinafter, with reference to Examples and Comparative Examples, the present invention is more specifically described. The present invention is not limited to Examples and Comparative Examples in any manner. The specific numeral values used in the description below, such as mixing ratios (contents), physical property values, and parameters can be replaced with the corresponding mixing ratios (contents), physical property values, parameters in the above-described “DESCRIPTION OF THE EMBODIMENT”, including the upper limit values (numeral values defined with “or less”, and “less than”) or the lower limit values (numeral values defined with “or more”, and “more than”).

### 1. Production of Wiring Circuit Board

According to the above-described method of producing a wiring circuit board, a wiring circuit board having a wire having the dimensions (width and thickness) shown in Table 1 was produced. The first conductor layer and the second conductor layer were formed on the seed layer made of chromium by electrolytic copper plating.

### 2. Evaluation

Using a microtome (manufactured by Leica Biosystems), a wiring circuit board after the formation of the second conductor layer was cut in the thickness direction (vertical direction). Next, the cross-section of the cut was photographed by using a CCD (manufactured by Olympus Corporation). The obtained image was magnified 100 times and observed, the depth of the concave portion of the side surface of the wire, and the presence or absence of a gap between the first conductor layer and the second conductor layer were measured. The results are shown in Table 1.

TABLE 1

| | Example | Example | Example | Example | Comp. | Comp. |
|---|---|---|---|---|---|---|
| | 1 | 2 | 3 | 4 | Ex. 1 | Ex. 2 |
| Width W21 of first | 13.3 | 15.2 | 17.9 | 18.0 | 18.1 | 13.1 |
| conductor layer (μm) | | | | | | |
| Thickness T21 of first | 13.9 | 16.0 | 17.2 | 7.9 | 22.0 | 21.0 |
| conductor layer (μm) | | | | | | |
| Width W11 of wire (μm) | 38.1 | 38.5 | 38.1 | 38.1 | 38.2 | 38.1 |
| Thickness T11 of wire (μm) | 38.3 | 41.0 | 42.4 | 41.2 | 41.9 | 41.3 |
| T11/T21 | 2.76 | 2.56 | 2.47 | 5.22 | 1.90 | 1.97 |
| W11/W21 | 2.86 | 2.53 | 2.13 | 2.12 | 2.11 | 2.91 |
| T21/W21 | 1.05 | 1.05 | 0.96 | 0.44 | 1.22 | 1.60 |
| Distances D11 and D12 | 12.40 | 11.65 | 10.10 | 10.05 | 10.05 | 12.50 |
| between side surfaces of | | | | | | |
| wire and first conductor | | | | | | |
| layer | | | | | | |
| Depth of concave portion | 0.10 | 0.28 | 0.40 | 0.01 | 0.81 | 0.72 |
| (μm) | | | | | | |

From a comparison between Example 1 and Comparative Example 2, and a comparison between Example 3 and Comparative Example 1, it is found that when the ratio (T11/T21) of the thickness T11 of the wire to the thickness T21 of the first conductor layer is 2.0 or more, the depth of the concave portion can be remarkably reduced.

Furthermore, from Examples 1 to 3, it is found that as the size (width W21 and thickness T21) of the first conductor layer is reduced more, and the distance D11, D12 between each of both side surfaces of the wire and the first conductor layer (i.e., the distance between the first conductor layer and the plating resist in the second conductor layer forming step) is increased more, consequently the depth of the concave portion can be reduced more.

Furthermore, from a comparison between Example 3 and Example 4, it is found that the depth of the concave portion can be reduced also by reducing the thickness T21 of the first conductor layer.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The wiring circuit board of the present invention can be used for connecting electronic components.

### DESCRIPTION OF REFERENCE NUMERALS

1 Wiring circuit board
2 Support portion
3A Wiring portion
11 Metal support layer
12 First insulating layer (an example of an insulating layer)
133A wire
1330 Concave portion
1331 First conductor layer
1332 Second conductor layer
S2 Side surface at one side of wire in width direction
S3 Side surface at the other side of wire in width direction
D11 Distance between side surface at one side of wire and the first conductor layer in width direction
D12 Distance between side surface at the other side of wire and the first conductor layer in width direction
T11 Thickness of wire
T21 Thickness of first conductor layer
W11 Width of wire
W21 Width of first conductor layer

1. A wiring circuit board comprising: a wiring portion; and a support portion that supports one end portion of the wiring portion,
wherein the wiring portion includes a metal support layer, an insulating layer disposed on the metal support layer, and a wire disposed on the insulating layer,
wherein at least in the wiring portion, the wire includes:
a first conductor layer disposed on the insulating layer, and
a second conductor layer covering the first conductor layer and being in contact with the insulating layer, and
wherein a ratio of a thickness of the wire to a thickness of the first conductor layer is 2.0 or more.

2. The wiring circuit board according to claim 1,
wherein a ratio of the thickness of the first conductor layer to a width of the first conductor layer is 0.3 or more and 1.1 or less.

3. The wiring circuit board according to claim 1,
wherein a width of the wire is larger than the width of the first conductor layer.

4. The wiring circuit board according to claim 1,
wherein a distance between each of both side surfaces of the wire and the first conductor layer in a width direction of the wire is 10.00 μm or more.

5. The wiring circuit board according to claim 1,
wherein the wire has a central portion and an end portion in a width direction of the wire, and
wherein the central portion protrudes toward an opposite side to the metal support layer with respect to the insulating layer in the thickness direction as compared with the end portion.

6. The wiring circuit board according to claim 1,
wherein the wire has a concave portion on each of both side surfaces of the wire in a width direction of the wire, and
wherein a depth of the concave portion is 0.7 μm or less.

7. The wiring circuit board according to claim 1,
wherein the support portion includes a wire that is continuous with the wire of the wiring portion, and
wherein the wire of the support portion includes the first conductor layer and the second conductor layer.

8. The wiring circuit board according to claim 1,
wherein the wiring circuit board includes a plurality of the wiring portions spaced away from each other, and
wherein the support portion supports one end portion of each of the plurality of the wiring portions.
